(19) United States
(12) Patent Application Publication
(10) Pub. No.: US 2020/0132980 A1
(43) Pub. Date: Apr. 30, 2020

(54) MICRO-MECHANICAL DEVICE WITH LOCAL ELECTROMAGNETIC ACTUATION

(71) Applicant: Sercalo Microtechnology Ltd, Schaan (LI)

(72) Inventors: Vincent Kuenlin, Neuchatel (CH); Cornel Marxer, Neuchatel (CH)

(21) Appl. No.: 16/670,837

(22) Filed: Oct. 31, 2019

(30) Foreign Application Priority Data
Oct. 31, 2018 (CH) 01326/18

(51) Int. Cl. G02B 26/08; B81B 3/00; H02K 1/12

(52) U.S. Cl. CPC G02B 26/085; B81B 3/0021; H02K 1/12; B81B 2203/06; B81B 2203/058; B81B 2203/0154; B81B 2201/042

(57) ABSTRACT

A micromechanical device with electromagnetic actuation includes a base and a micro electro mechanical system (MEMS). The MEMS includes a mobile rotating element based on one or two axes of rotation. The base includes stators each forming a first internal pole, an external pole and an air gap. In order to increase the reliability and the mechanical stability of the device, the first internal poles are mounted in a connected manner to each other onto the base.

### CROSS-REFERENCE TO RELATED APPLICATION

This application claims priority to Swiss Patent Application No. 01326/18 filed Oct. 31, 2018, the entirety of which is incorporated by this reference.

This invention is related to electromechanical microsystems, better known under the MEMS name, from the English Micro Electro Mechanical Systems. It concerns more specifically a micromechanical device including a mobile rotating element based on at least one rotation axis, and means of actuation of this electromagnetic type rotating element.

Such devices are generally optical devices in which the rotating element is comprised of a mirror connected to a fixed frame through two elastic beams in torsion defining the mirror's axis of rotation. Alternately, the rotating element is mobile based on two axes of rotation. The mirror is then connected to a first mobile frame using two torsion beams, which is itself connected to the fixed frame through two other torsion beams. Whether it is mobile based on one axis or two axes of rotation, the mirror thus mounted allows redirecting a light beam between different fixed angular positions or scanning an angular space using a light beam. Such devices equip in particular optic spectrometers, printers, medical imagery devices, light sensors and numerous other devices including an optical control.

Among the aforementioned devices, we are interested in devices actuated electromagnetically using a rotor made up of at least one integrally-mounted arc runner of the rotating element, and a stator including two opposite magnetic poles separated by an air gap in which the rotor is placed. More specifically, we are interested here in devices equipped with a base on which an MEMS is mounted including a mobile rotating element based on at least one axis of rotation and at least a first rotor made up of a conductor line, which includes two segments detached from the rotating element so as to define two empty spaces interior and exterior to the rotor. Two stators, each made up of an internal pole, an external pole, and an air gap together defining a magnetic field B̅, are mounted on the base and each of the segments is arranged in one of the air gaps perpendicularly to field B̅, such that the internal and external poles are placed in the empty spaces internal and external to the rotor respectively. Such devices are described in document EP 2 990 375 B1. The positioning of the conductor line segments inside the air gaps has the effect of confining magnetic field B̅ to the strict vicinity of these useful conductor line segments and to the exclusion of any other unnecessary portion of the device. This confinement is of great interest since it allows increasing magnetic field B̅ locally and thus the actuation force of the rotating mirror, while still limiting the losses of magnetic power observed in more standard configurations of the stators in relation to the rotors. For more information on the structure of such devices and on the advantages that it provides, we will refer to document EP 2 990 375 B1, and in particular to FIG. 4 which represents a perspective view of a device with electromagnetic actuation of a mobile mirror based on two axes of rotation.

The device represented in FIG. 4 of patent EP 2 990 375 B1, although very efficient, is not exempt from defects, in particular regarding reliability. We understand well that with dimensions in the range of square centimeters, the type of device described in document EP 2 990 375 B1 requires great precision, in particular regarding the positioning of the stators in relation to the rotors. In fact, the conductor line segments placed inside the air gaps have little room to move under the effect of the magnetic field. A rigorous alignment of these segments with respect to the air gaps is therefore essential for the proper functioning of the device. The mounting of the MEMS and the stators on the base is thus done with the greatest care. But reliability tests taking the form of temperature cycles over the duration of one month show that the stators move on the base under the effect of thermal stress. The reason for this is the deterioration of the epoxy glue used to fix the stators onto their base, combined with the attraction and/or repulsion forces exercised together by neighboring stators. Repeated impacts or vibrations lead to the same result, which is explained also here by the pressures that the stators exert on each other and the breakdown of the glue. We observe that the breakdown of the glue is between the base and the stators, that is, at the point where the pressures are exerted in shear. The glue resists much better to simple traction forces. The movements observed, although small (in the range of one tenth of one millimeter), are enough to disturb the functioning of such devices, whose dimensions are themselves very small. We observe in particular that the conductor line segments are blocked or broken inside the air gaps, because of the change of position of the stators. The electromagnetic actuation is thus inoperative and the mobile mirror is blocked in a fixed position. It is important to observe, for the proper understanding of the invention, that the movement of the stators during reliability tests is caused by the combination of the deterioration of the glue and magnetic forces exerted between stators. These factors taken separately do not produce the movement of one or several elements on the base. The MEMS, for example, which is also glued to the base, but is not subjected to any force, remains fixed during reliability tests.

This invention has the goal of remedying this disadvantage, by offering a micromechanical device in which the stators are mounted on the base in a fixed manner relative to each other.

More specifically, the invention concerns a micromechanical device with electromagnetic actuation including a base and an MEMS mounted on this base, the MEMS including a mobile rotating element based on a first axis of rotation and a first rotor made up of a conductor line, which includes two first segments detached from the rotating element so as to define two empty spaces internal and external to the first rotor. The base even includes two first stators each made up of a first internal pole, a first external pole, and a first air gap together defining a magnetic field B̅ ′, each of the first segments being configured in one of the first air gaps perpendicularly to field B̅, such that the first internal and external poles are placed in the empty spaces internal and external to said first rotor respectively. As per the invention, the first internal poles are mounted on the base connected to each other. In one particularly interesting iteration of the device as per the invention, the first internal poles make up a single strip part.

By virtue of the fact that the internal poles of the stators are mounted connected to each other, and in particular are presented as a single part, the magnetic forces that exercise pressure in shear between the stators and the base cannot produce any movement relative to each other. Only the complete unit made up of all the poles internal to the rotors can move theoretically, but it does not undergo any specific pressures that, added to the deterioration of the epoxy glue, could generate accidental movement. The characteristics and advantages of this invention will appear more clearly upon reading the following description, given only as an example, and made in reference to the appended drawings.

### BRIEF DESCRIPTION OF THE DRAWINGS

FIG. 1 is a perspective view of a first iteration of a device with electromagnetic actuation as per the invention including a rotating element based on a first axis of rotation,

FIG. 2 represents a longitudinal section of the device illustrated in FIG. 1,

FIGS. 3 and 4 are longitudinal sections respectively of a second and third iterations of a device as per the invention,

FIG. 5 is a perspective view of a first iteration of a device with electromagnetic actuation as per the invention including a rotating element based on a first and second axis of rotation,

FIG. 6 is a cutaway view of the device illustrated in FIG. 5,

FIGS. 7 and 8 are cutaway views respectively of a second and third iterations of a device as per the invention including a rotating element based on a first and second axis of rotation, and

FIG. 9 is a cutaway view of a variant of the third iteration illustrated in FIG. 8.

### DETAILED DESCRIPTION OF THE INVENTION

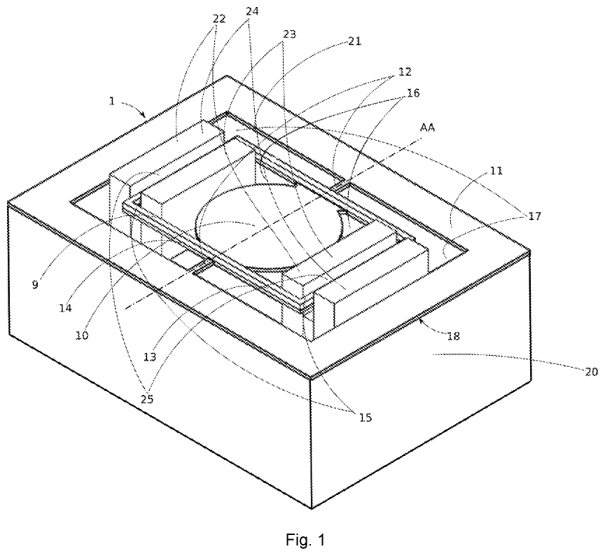

The micromechanical device with local electromagnetic actuation represented in FIG. 1, and referenced as a whole 1, includes classically a rotating element 10, mounted mobile in rotation based on a first axis of rotation AA on a fixed frame 11, through two torsion beams 12. Rotating element 10 is an optically active element, like a mirror, a diffraction grating, a lens or any other component intended to interact with a light beam. It is mounted connected in rotation with a rotor 13 made up of a mobile frame 14 topped with a conductor line 9. Rotor 13 is of essentially rectangular or square geometry, and includes two segments 15 detached from rotating element 10, parallel to axis of rotation AA and symmetrical compared to said axis of rotation AA. Each of the segments 15 is separated, on one hand, from the rotating element 10 by an empty space 16 internal to said rotor 13, and on the other hand, from fixed frame 11 by an empty space 17 external to said rotor 13. The function of the internal 16 and external 17 spaces will be described later. The unit composed of rotating element 10, fixed frame 11, torsion beams 12 and rotor 13 is made of a single piece 18 from a silicon monoxide plate (SOO, from the English Silicon On Oxide), by photolithography operations, and is known under the name of MEMS (from the English Micro Electro Mechanical System). Conductor line 9 is classically a metallic track obtained through a sputter deposition process. The dimension of the unit is around a square centimeter.

Fixed frame 11 is mounted glued onto a metallic base 20 made up of a parallelipiped rectangle including a recess 21 of dimensions chosen to receive rotating element 10, rotor 13, and all parts of device 1. Two stators 22 each including two poles 23, 24 separated from each other by an air gap 25, are mounted on metallic base 20, in recess 21, so as to receive in air gaps 25 segments 15 of rotor 13. Poles 23 located in empty spaces 16 internal to rotor 13 are called internal poles 23, whereas poles 24 being placed in empty spaces 17 external to rotor 13 are called external poles 24. In this configuration, rotating element 10 is actuated in rotation by stators 22 that work together with segments 15 of rotor 13, without loss of magnetic power and with an efficiency that is greater than that of legacy devices.

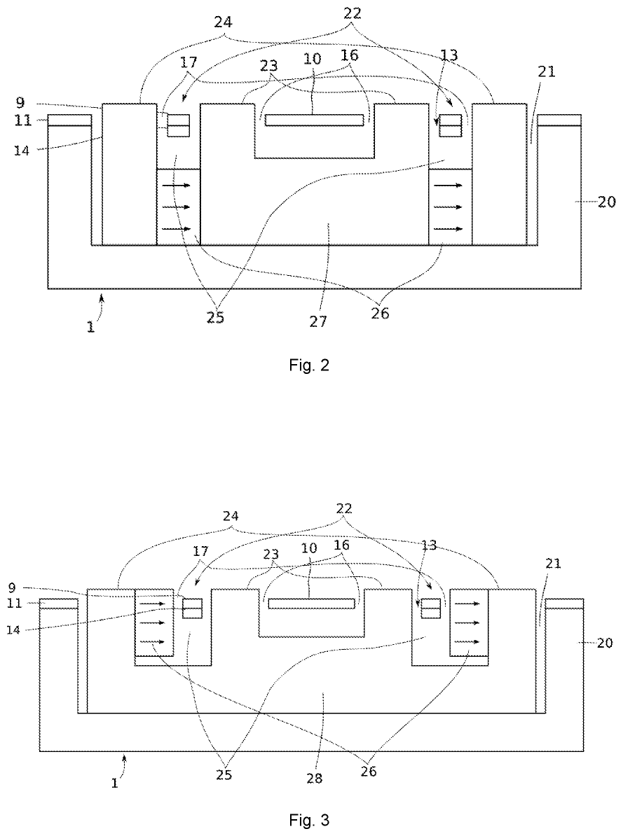

We refer now to FIG. 2 representing a longitudinal sectional view of the described device in relation to FIG. 1. Metallic base 20 forms a parallelipiped cavity onto which fixed frame 11 is glued, connected to rotor 13 and rotating element 10. Stators 22 are glued onto base 20, in recess 21, so as to receive segments 15 of rotor 13 in their air gaps 25. A magnet 26, generating a magnetic field B̅, is arranged between internal poles 23 and external poles 24, thus defining air gap 25 of each stator 22. Base 20 is comprised of a non-magnetic metal so as not to deviate magnetic field B̅ circulating between internal poles 23 and external poles 24.

As per the invention, internal poles 23 are mounted connected to each other on base 20. More precisely, poles 23 are made up of a U-shaped part 27, with a single strip, mounted on base 20 so as to become inserted into internal empty spaces 16. This way, internal poles 23 do not exert any mutual pressures likely to produce movement of one or the other under the effect of the aging of the glue and the forces present. External poles 24 are themselves connected to internal poles 23 through magnets 26, which are glued on one side to internal poles 23 and on the other side to external poles 24. Thus, the two stators 22 make up a unit of parts assembled by gluing, and the pressures experienced by the unit are internal but not external. The unit made up of the two stators 22 therefore does not move as a whole, but it experiences internal magnetic pressures of three types: From internal pole 23 towards internal pole 23, from internal pole 23 towards external pole 24, and from external pole 24 towards external pole 24. The first ones do not produce any movement because of the fact that internal poles 23 only make up one part 27. The second and third types of pressures, of attraction and repulsion, may induce shear forces, but only in the case of repulsion between an opposite internal pole 23 and an external pole 24, or between the two external poles 24. In these two cases, the gluing of external poles 24 to U-shaped part 24, through magnets 26, ensures the stability of external poles 24. Thus mounted, micromechanical device 1 successfully undergoes the thermal stress tests, without movement of stators 22 and therefore without blockage of rotor 13.

FIG. 3 represents a longitudinal sectional view of a second iteration of a device with local electromagnetic actuation as per the invention. On this FIG. 3, we find an MEMS 18 made up of a rotating element 10 mounted on a fixed frame 11 through torsion beams 12, fixed frame 11 being mounted glued onto a metallic base 20. Stators 22 are arranged in recess 21 such that segments 15 are placed in air gaps 25. This second iteration is distinct from the first in that external poles 24 and internal poles 23 of the two stators 22 are made up of a part 28 in a triple U shape of a single strip, mounted on metallic base 20 so as to become inserted into internal empty spaces 16 and external empty spaces 17. Magnets 26 are glued, inside air gaps 25, on the internal side of external poles 24, so as to generate a magnetic field B̅. In a variant, magnets 26 are glued on the external side of internal poles 23. Metallic base 20 is a non-magnetic metal so as not to disturb magnetic field B̅ inside air gaps 25. In this configuration, the two stators 22 make up a unit with a single strip including two glued parts, namely magnets 26. As before, the pressures experienced by the unit are internal but not external, and they only act on magnets 26. These pressures are of the attraction or repulsion type, but not the shear type, and in this configuration, the epoxy glue presents good resistance. This iteration therefore presents an advantage over the previous iteration, namely that the shear forces between poles 23, 24 and base 20 are totally absent, while there are residual shear forces in the previous iteration. Resistance to the thermal stress test is further increased, and we still observe that the mounting of such a device is broadly facilitated in comparison to a legacy device, since there is only one part to be aligned in relation to the MEMS 18, namely part 28.

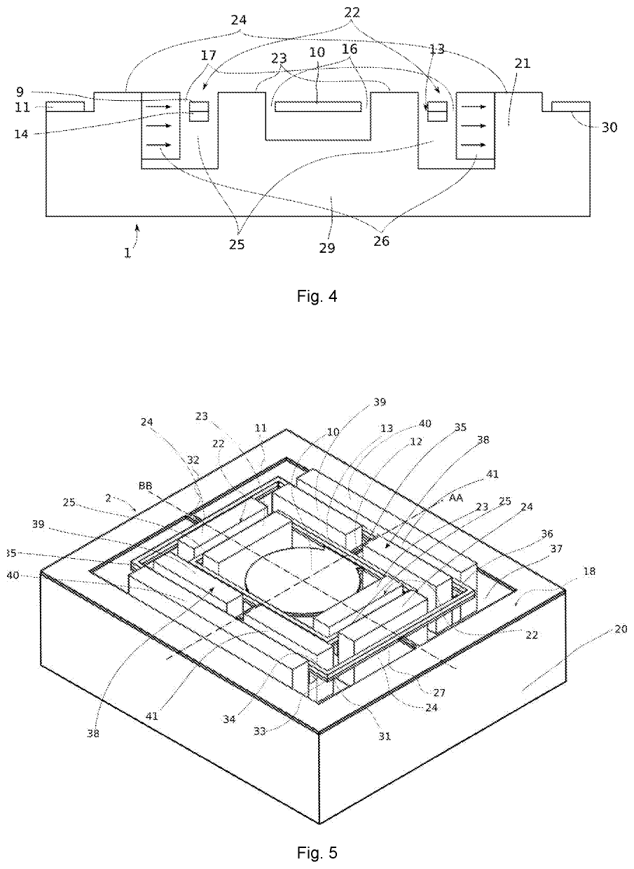

We refer now to FIG. 4, which is a longitudinal sectional view of a third iteration of a device with local electromagnetic actuation as per the invention. This iteration is distinguished from the previous one in that base 20 and part 28 in a triple U shape are combined in one part 29 with a single strip. A flat surface 30, running on the edge of part 29, is designed to receive fixed frame 11. Part 29 is made out of magnetic material so as to induce a magnetic field B̅ in air gaps 25. This iteration presents all the advantages of the previous iteration, namely the absence of shear forces between stators 22 and the base, plus some others. First of all, the structure is simplified and the procedure of the gluing of part 28 on base 20 is eliminated. At the same time, any potential gluing problem or movement of part 28 with regard to the base disappears simultaneously. The alignment of MEMS 18 with stators 22 is done in a single procedure, the procedure of gluing fixed frame 11 onto surface 30. In order to facilitate the alignment of the MEMS 18 with respect to part 29, pins 8 arranged at the four corners of base 20 are received in notches 7 made in the four corners of MEMS 18. The number of mounting procedures and manufacturing costs are therefore reduced, while the reliability of device 1 is further increased.

FIG. 5 is a perspective view of a device with electromagnetic actuation 2 as per the invention, including a rotating element based on a first and a second axis of rotation, AA and BB respectively. This type of device is described in detail in document EP 2 990 375 B1, and for more explanations on its structure and its advantages, we will refer to this patent. We confine ourselves in the following paragraph to presenting the elements useful for the understanding of the invention. The structure of device 2 is completely similar to the structure of device 1, apart from the fact that it includes a second axis of rotation. Rotating element 10 is mounted connected in rotation to the first rotor 13 on a second rotor 31 through torsion beams 12 defining axis AA, the second rotor 31 itself being mounted free in rotation on fixed frame 11 using torsion beams 32 defining axis BB. The second rotor 31 is made up of a mobile frame 33 topped with a conductor line 34, and includes two second segments 35 separated from the first rotor 13 by an empty space 36 internal to the second rotor 31 on the one hand, and separated from fixed frame 11 by an empty space 37 external to said second rotor 31 on the other hand. Electromagnetic actuation device 2 includes even two second stators 38 each made up of a second internal pole 39, a second external pole 40, and a second air gap 41 together defining a magnetic field B̅. Each of the second segments 35 is arranged in one of the two air gaps 41 perpendicularly to field B̅, the second internal poles 39 and external poles 40 being placed in the empty spaces 36 internal to and 37 external to the second rotor 31. In principle, the operation of this device is identical to the one of the device described with relation to FIG. 1, apart from the fact that rotating element 10, driven by the first and the second rotors 13, 31, may be actuated in rotation based on the two axes AA and BB.

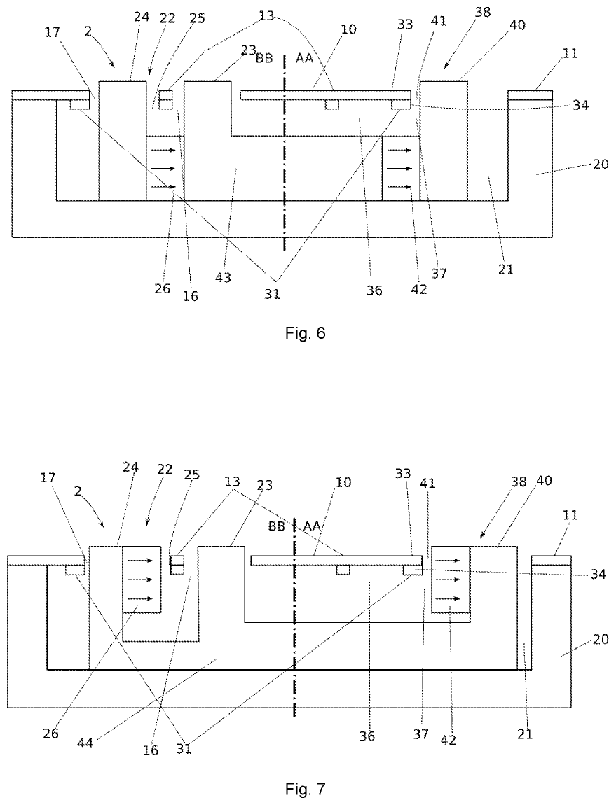

We refer now to FIG. 6 that presents an AB section of device 2 described in relation to FIG. 5. This sectional view is very similar to the one described in relation to FIG. 2. A first and a second stator 22, 38 are mounted glued onto base 20. They receive in their respective air gaps 25, 41 the first and second segments 15, 35. A magnet 42 is interposed between the second internal poles 39 and external poles 40 of the second stator 38. As per the invention, the first and second internal poles 23, 39 are mounted connected onto base 20. More precisely, internal poles 23, 39 are composed of a single part 43, forming a cross in the plane of base 20, topped with fours bars that are inserted into internal empty spaces 16, 36. The external poles 40 are themselves connected to internal poles 39 through magnets 42, which are glued on one side to internal poles 39 and to external poles 40 on the other side. This iteration is similar to the one illustrated in FIG. 2, and presents the same advantages as the latter.

In the same way, the iteration illustrated in FIG. 7 is similar, in principle, to the iteration described with respect to FIG. 3. This iteration is distinguished from the previous one in that internal and external poles 39, 40 are made up of a single strip part 44, which is mounted glued onto base 20. Here again, the advantages related to this iteration are already described in relation to FIG. 3.

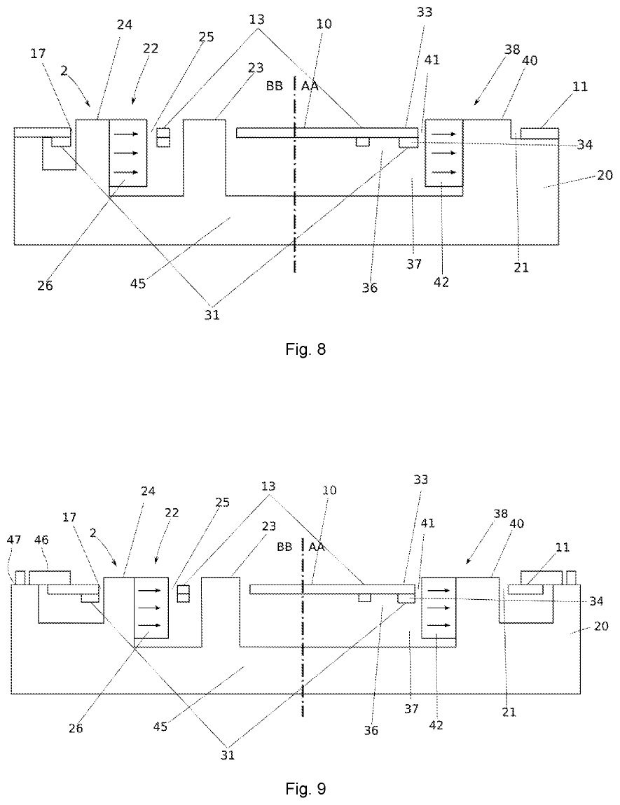

We refer now to FIG. 8, which represents a third iteration of device 2 as per the invention. In principle, this iteration is similar to the iteration illustrated in FIG. 4. It is distinguished from the previous one in that part 44 makes up, with base 20, a single strip part 45, on which the MEMS 18 is mounted. In this very beneficial iteration, the first and second stators 22, 38 are combined with base 20 and the only parts glued are magnets 26, 42. The advantages of this iteration are made clear in relation to FIG. 4.

Finally, we refer to FIG. 9 that illustrates a variant of the previous iteration. In this variant, the MEMS 18 is not directly attached to part 45, but rather indirectly, through a plate 46 which is itself welded to part 45 in four points 47. Plate 46 is made out of a metal having a coefficient of thermal expansion close to that of silicon, for example KOVAR® (a nickel-cobalt ferrous alloy) or stainless steel. It includes essentially rectangular cutouts 47 in the vicinity of the welding points 47, intended to absorb through elasticity the difference of thermal expansion between plate 46 and part 45. The MEMS 18 is glued on or under plate 46. In this configuration, the few residual tensions due to the variations of temperature are absorbed by intermediary plate 46, and the MEMS 18 is free from these tensions. The resistance of device 2 to thermal stress is even more improved.

A device with local electromagnetic actuation has thus been described. Certainly, this invention is not limited to the iterations described above, but extends to all variants within the scope of skilled persons, becoming part of the framework of the claims below.

1-8. (canceled)

9. A micromechanical device with electromagnetic actuation, comprising:
a base;
a plate;
a micro electro mechanical system (MEMS) mounted indirectly through the plate onto the base, the MEMS comprising a rotating element having a first axis of rotation and a first rotor comprising at least one first conductor line and two first segments detached from the rotating element so as to define two empty spaces internal and external to the first rotor,
two first stators each made up of a first internal pole, a first external pole and a first air gap together defining a magnetic field B̅, each one of the two first segments arranged in one of the first air gaps perpendicularly to field B̅, so that the first internal poles and first external poles are placed in the two empty spaces internal to and external to the first rotor,
the first internal poles are mounted in a connected manner to each other onto the base and the MEMS is mounted indirectly through the plate onto the base.

10. The micromechanical device of claim 9, wherein the MEMS is fixed to the base using an intermediary metal plate with a coefficient of thermal expansion close to that of silicon.

11. The micromechanical device of claim 10, wherein the intermediary plate includes essentially rectangular cutouts in a vicinity of welding points that attach the intermediary plate to the base.

12. The micromechanical device of claim 9, wherein:
the rotating element is movable about a second axis of rotation;
the MEMS further comprises a second rotor comprising a second conductor line, and including two second segments detached from the first rotor to define two empty spaces internal to and two empty spaces external to the second rotor,
two second stators each comprising a second internal pole, a second external pole and a second air gap together defining a magnetic field B̅, each one of the two second segments being arranged in one of the two air gaps perpendicularly to field B̅, such that the second internal and external poles are placed in the two empty spaces internal and external to the second rotor; and
the first and second internal and external poles are mounted onto the base and are connected to each other.

13. The micromechanical device of claim 12, wherein the first and second internal poles form a single strip.

14. The micromechanical device of claim 12, wherein the first and second stators comprise a magnet attached to the respective first and second internal poles, the respective first and second external poles attached to the magnet to define the first and second air gaps.

15. The micromechanical device of claim 12, wherein the first and second stators comprise a magnet attached to the first and second external poles, the first and second external poles connected respectively to the first and second internal poles.

16. The micromechanical device of claim 12, wherein the first and second internal and external poles are combined with the base, forming a single strip of ferromagnetic material.
